(19) United States
(12) Patent Application Publication
(10) Pub. No.: US 2013/0255987 A1
(43) Pub. Date: Oct. 3, 2013

(54) MOUNTING DEVICE FOR FAN

(71) Applicants: HONG FU JIN PRECISION INDUSTRY (SHENZHEN) CO., LT, Shenzhen (CN); HON HAI PRECISION INDUSTRY CO., LTD., New Taipei (TW)

(72) Inventor: XIU-QUAN HU, Shenzhen (CN)

(73) Assignees: HON HAI PRECISION INDUSTRY CO., LTD., New Taipei (TW); HONG FU JIN PRECISION INDUSTRY (ShenZhen) CO., LTD., Shenzhen (CN)

(21) Appl. No.: 13/688,437

(22) Filed: Nov. 29, 2012

(30) Foreign Application Priority Data
Mar. 27, 2012 (CN) 201210083904.6

(51) Int. Cl. H05K 7/20; H05K 5/02

(52) U.S. Cl. CPC H05K 7/20172; H05K 5/0221
USPC 174/50; 248/674

(57) ABSTRACT

A mounting device for a fan includes a bracket and two latches. The bracket includes a top wall, a bottom wall and a vent plate connecting the top wall to the bottom wall. Each of the top wall and the bottom wall defines a cutout extending to the vent plate. Each of the two latches is fixed on each of the top wall and the bottom wall and includes an elastic arm and a fixing tab located on the elastic arm. The elastic arm is fixed on an inner surface of each of the top wall and the bottom wall. The fixing tab extends out of each cutout of the top wall and the bottom wall, and the elastic arm is resiliently deformable to retract the fixing tab into the bracket.

### BACKGROUND

The disclosure generally relates to mounting devices for fans, and especially to a mounting device for retaining a fan to a chassis.

### DESCRIPTION OF RELATED ART

Electronic components in computers, such as central processing units and power supplies, generate a large mount of heat. A fan module is usually provided for the power supply to assist in cooling the electronic components. The fan is generally mounted in a bracket, and then the bracket is mounted in each computer enclosure by screws, a process requires a screw driver to secure the bracket with screws. Disassembly or reassembly of the fan is tedious and inconvenient.

Therefore, there is room for improvement within the art.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is an isometric and partially exploded view of an electronic device enclosure in one embodiment.

FIG. 2 is similar to FIG. 1, but shown from another aspect.

FIG. 3 is a partially assembled view of the electronic device enclosure of FIG. 2.

FIG. 4 is an assembled view of the electronic device enclosure of FIG. 1.

FIG. 5 is similar to FIG. 4, but shown from another aspect.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean at least one.

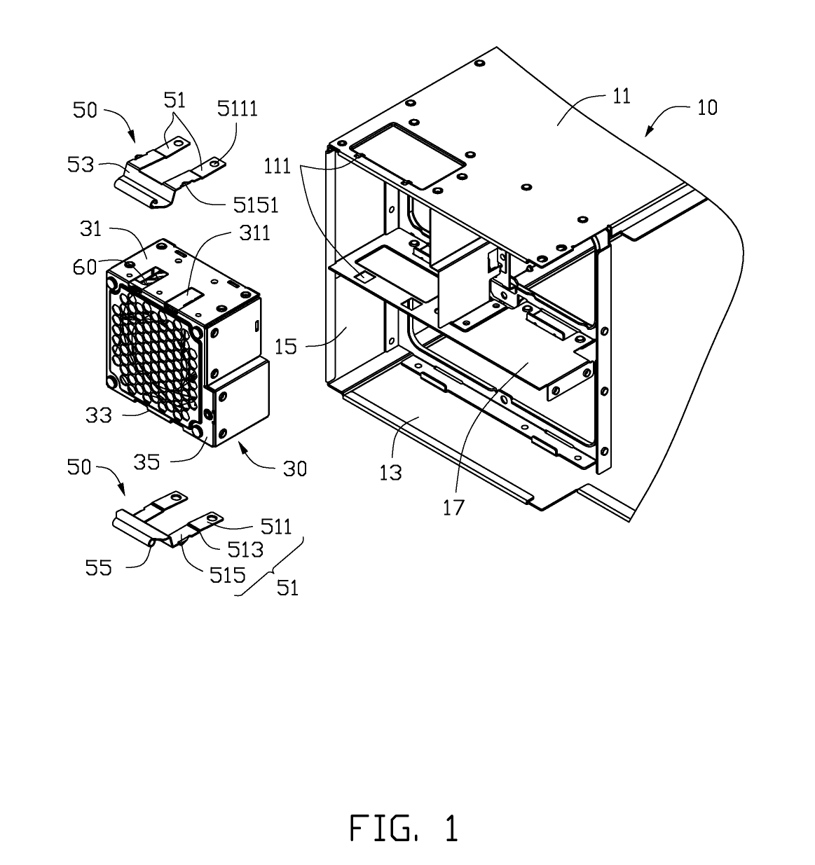

FIG. 1 illustrates one embodiment of an electronic device enclosure. The electronic device enclosure includes a chassis 10, a plurality of brackets 30, and two latches 50. Each of the plurality of brackets 30 can receive a fan 60.

The chassis 10 includes a top plate 11, a bottom plate 13, a side plate 15, and a dividing plate 17. The top plate 11 is substantially parallel to the bottom plate 13. The side plate 15 is substantially perpendicularly connected to the top plate 11 and the bottom plate 13. The dividing plate 17 is substantially perpendicularly connected to the side plate 15 and located between the top plate 11 and the bottom plate 13. The top plate 11, the bottom plate 13, and the dividing plate 17 cooperatively define a plurality of receiving space for receiving the plurality of brackets 30. Each of the top plate 11 and the dividing plate 17 defines two retaining holes 111 corresponding to each bracket 30.

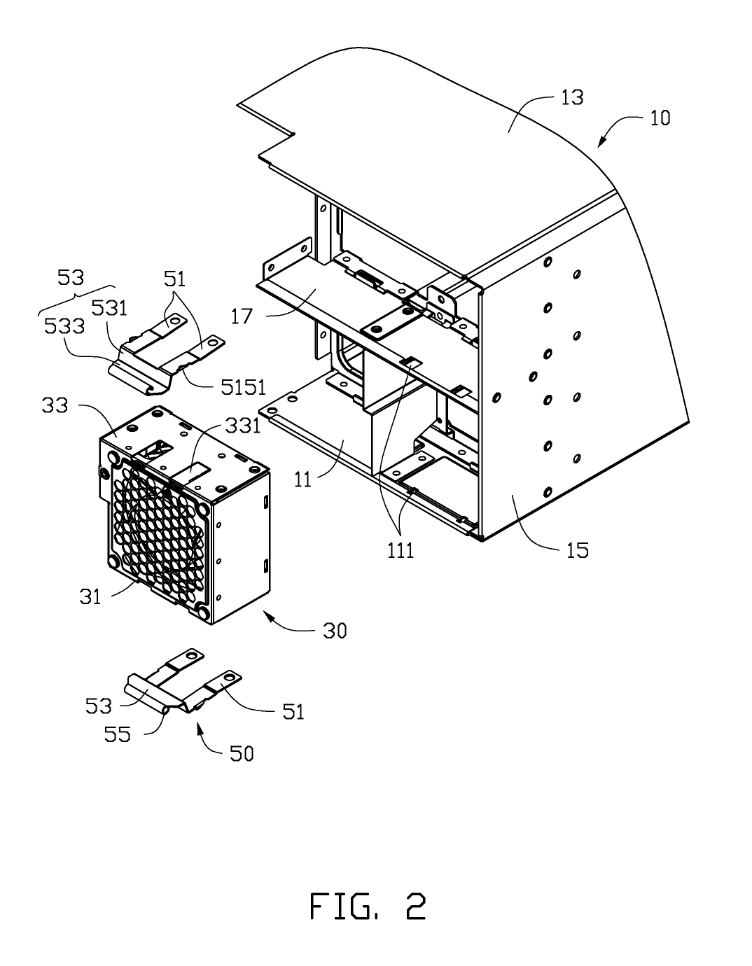

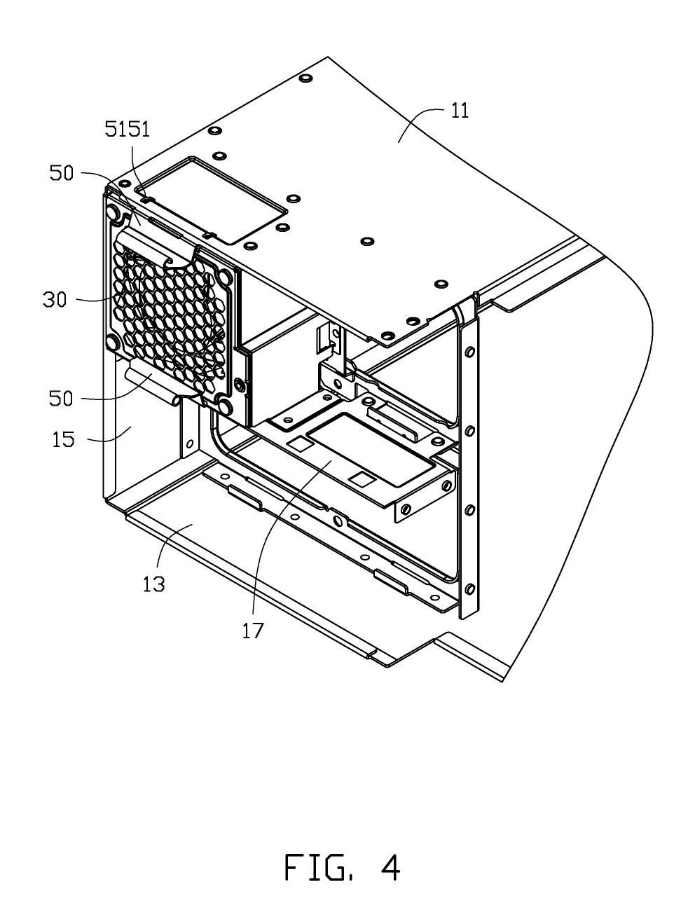

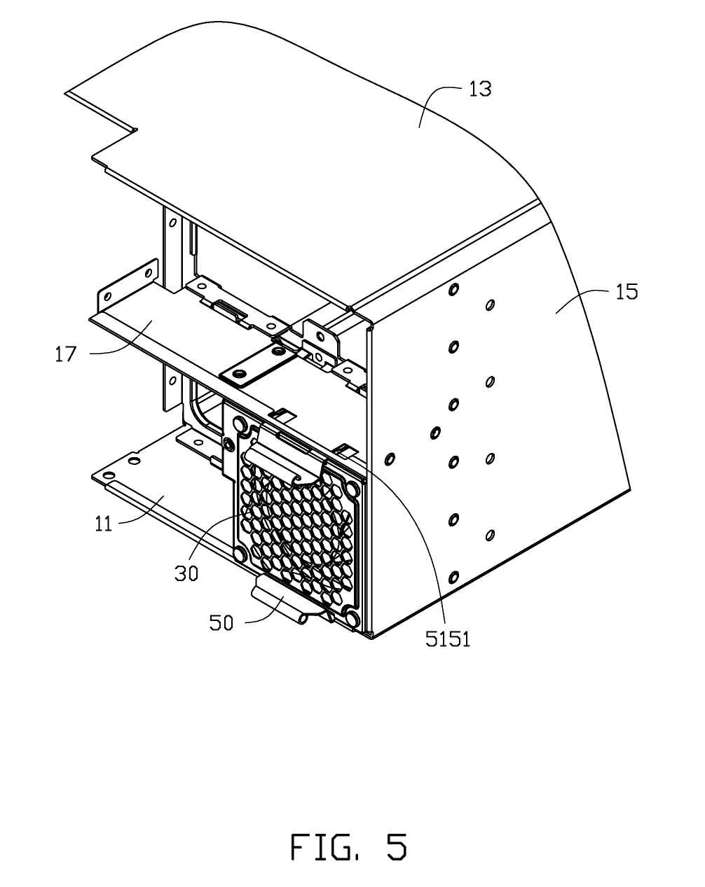

FIGS. 1-5 illustrate one bracket 30 as an example. The bracket 30 includes a top wall 31, a bottom wall 33, and a vent plate 35. The top wall 31 and the bottom wall 33 are parallel to each other and perpendicularly connected to two opposite edges of the vent plate 35. Each of the top wall 31 and the bottom wall 33 defines two cutouts 311 extending to the vent plate 35, corresponding to the two latches 50. Two positioning posts (not shown) protrude inwardly from inner surface of each of the top wall 31 and the bottom wall 33.

Each of the two latches 50 includes two elastic arms 51, a handle 55, and a converting portion 53 connecting the two elastic arms 51 to the handle 55. Each of the two elastic arms 51 includes a securing piece 511, a connecting piece 513, and an elastic piece 515. The connecting piece 513 connects the securing piece 511 to the connecting piece 513. The securing piece 511 and the connecting piece 513 are located on two opposite sides of the connecting piece 513. In one embodiment, a first obtuse angle is defined between the connecting piece 513 and the securing piece 511, and a second obtuse angle is defined between the connecting piece 513 and the elastic piece 515. The securing piece 511 defines a securing hole 5111, corresponding to each positioning post. A fixing tab 5151 extends outwards from each elastic piece 515, corresponding to each retaining hole 111. The converting portion 53 includes a first converting piece 531 and a second converting piece 533, connected to the first converting piece 531. The two elastic arms 51 are located on an edge of the first converting piece 531. The handle 55 extends inside from a distal end of the second converting piece 533. In one embodiment, the handle 55 is curved shaped.

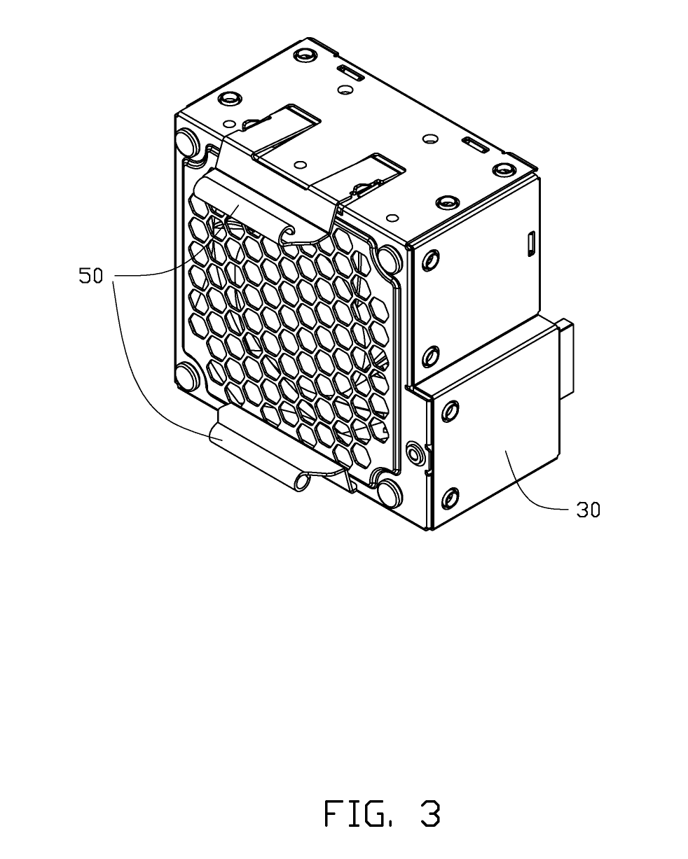

FIGS. 3-5 shows that in assembly, the two latches 50 are then installed one at a time in the same manner, and only the installation of one of the two latches 50 is described below. The two elastic arms 51 of the latch 50 are partially inserted into the two cutouts 311 of the top wall 31 and located on inner side of the top wall 31. The two positioning posts are inserted into the securing holes 5111 of the two elastic arms 51, to secure the latch 50 to the top wall 31. Each connecting piece 513 of each elastic arms 51 abuts an edge of each cutout 311. The two elastic arms 51 protrude through the two cutouts 311. The converting portion 53 of the latch 50 is located on the front of the bracket 30.

A forcing action is applied to the handle 55 of each of the two latches 50, the two elastic arms 51, of each latch 50, are elastically deformable to retract the fixing tab 5151 into the corresponding cutout 311. The bracket 30 is moved towards the receiving space of the chassis 10, until each fixing tab 5151 is aligned with each retaining hole 111.

The two elastic arms 51 rebound to engage each fixing tab 5151 into each retaining hole 111, to secure the bracket 30 to the chassis 10.

When detaching the bracket 30, the handle 55 of the two latches 50 is pressed towards each other, and the two elastic arms 51 are elastically deformable to disengage each fixing tab 5151 from each retaining hole 111. The bracket 30 can be thus removed out of the chassis 10.

It is to be understood, however, that even though numerous characteristics and advantages have been set forth in the foregoing description of embodiments, together with details of the structures and functions of the embodiments, the disclosure is illustrative only and changes may be made in detail, especially in the matters of shape, size, and arrangement of parts within the principles of the disclosure to the full extent indicated by the broad general meaning of the terms in which the appended claims are expressed.

What is claimed is:

1. A mounting device for a fan, comprising:
a bracket comprising a top wall, a bottom wall, and a vent plate, connecting the top wall to the bottom wall; and each of the top wall and the bottom wall defining a cutout; and
two latches being fixed on the top wall and the bottom wall, each of the two latches comprising an elastic arm and a fixing tab located on the elastic arm;
wherein the elastic arm of each of the two latches is fixed on an inner surface of each of the top wall and the bottom wall; the fixing tab of each of the two latches extends out of the cutout of each of the top wall and the bottom wall; and the elastic arm, of each of the two latches, is resiliently deformable to engage the fixing tab of each of the two latches into the bracket.

2. The mounting device of claim 1, wherein the elastic arm comprises a securing piece and an elastic piece, and the securing piece is substantially parallel to the elastic piece.

3. The mounting device of claim 2, wherein the securing piece is attached to each of the top plate and the bottom plate, and the fixing tab protrudes from the elastic piece.

4. The mounting device of claim 2, wherein the elastic arm further comprises a connecting piece connecting the securing piece and the elastic piece, and the securing piece and the elastic piece are located on two opposite sides of the connecting piece.

5. The mounting device of claim 1, wherein each of the two latches further comprises a handle extending out of the bracket, and the handle is configured to deform the elastic arm.

6. The mounting device of claim 5, wherein a distal end of handle is curved.

7. The mounting device of claim 5, wherein each of two latches further comprises a converting portion, and the converting portion connects the handle to the elastic arm.

8. An electronic device enclosure, comprising:
a chassis comprising a top plate and a dividing plate, each of the top plate and the dividing plate defining a retaining hole;
a bracket comprising a top wall, a bottom wall and a vent plate connecting the top wall to the bottom wall, each of the top wall and the bottom wall defining a cutout extending to the vent plate; and
two latches, each of the two latches being fixed on each of the top wall and the bottom wall and comprising an elastic arm and a fixing tab located on the elastic arm;
wherein the elastic arm of each of the two latches is fixed on an inner surface of each of the top wall and the bottom wall; the fixing tab of each of the two latches extends out of each cutout and engages in the retaining hole, to secure the bracket between the top wall and the dividing plate; and the elastic arm is resiliently deformable to retract the fixing tab into the cutout of each of the top wall and the bottom wall, to disengage the fixing tab from the retaining hole.

9. The electronic device enclosure of claim 1, wherein the elastic arm comprises a securing piece and an elastic piece, and the securing piece is substantially parallel to the elastic piece.

10. The electronic device enclosure of claim 2, wherein the securing piece is attached to each the top wall and the bottom wall, and the fixing tab protrudes from the elastic piece.

11. The electronic device enclosure of claim 2, wherein the elastic arm further comprises a connecting piece connecting the securing piece and the elastic piece, and the securing piece and the elastic piece are located on two opposite sides of the connecting piece.

12. The electronic device enclosure of claim 1, wherein each of the two latches further comprises a handle, the handle is configured to deform the elastic arm.

13. The electronic device enclosure of claim 5, wherein the handle is curved shaped.

14. The electronic device enclosure of claim 5, wherein each of the two latches further comprises a converting portion, and the converting portion connects the handle to the elastic arm.
